(19) United States
(12) Patent Application Publication
(10) Pub. No.: US 2009/0146030 A1
(43) Pub. Date: Jun. 11, 2009

(54) BRACKET FOR HARD DISK DRIVE

(75) Inventors: XIAO-ZHU CHEN, Shenzhen (CN); KE SUN, Shenzhen (CN); ZHEN-XING YE, Shenzhen (CN); MING-KE CHEN, Shenzhen (CN)

Correspondence Address: PCE INDUSTRY, INC.;ATT. Steven Reiss, 458 E. LAMBERT ROAD, FULLERTON, CA, 92835, US

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 11/965,747

(22) Filed: Dec. 28, 2007

(30) Foreign Application Priority Data
Dec. 6, 2007 (CN) 200710202904.2

(51) Int. Cl. A47B 96/06; G06F 1/16; H05K 5/00; H05K 7/00

(52) U.S. Cl. 248/213.2

(57) ABSTRACT

A bracket is mounted to a computer and configured for fixing a hard disk drive. The computer includes a case with a rear wall, and a main board mounted in the case. The main board includes an expansion socket set thereon. The bracket includes a first supporting member including an inserting portion extending therefrom configured for engaging with the expansion socket of the main board, a second supporting member mounted to the first supporting member and configured for being mounted to the rear wall of the computer, and a fixing member mounted to the first supporting member and configured for mounting the hard disk drive.

### BACKGROUND

1. Field of the Invention

The present invention relates to brackets, and more particularly to a bracket for a hard disk drive.

2. Description of Related Art

With advances in computer technology, computers have become needful tools in people's daily life and in business. Thus, a great deal of data storage space for storing information is needed, which is loaded in hard disk drives. Generally, in a personal computer, the hard disk drives are accommodated in a bracket that is mounted in the computer, but a capacity of the bracket is limited, thus the bracket can only receive a limited quantity of hard disk drives. On the other hand, a plurality of expansion sockets for mounting expansion cards, such as peripheral component interconnects (PCI) cards, accelerated graphics ports (AGP) cards, and industrial standard architecture (ISA) interconnects cards, is set on a main board in the computer, but some or all of the expansion sockets are always left unused, which leads to a waste of the expansion sockets and a space above the sockets.

What is needed, therefore, is a bracket for a hard disk drive which advantageously utilizes the unused expansion sockets and a space above the expansion sockets in the computer for receiving the hard disk drive.

### SUMMARY

An exemplary bracket is mounted to a computer and configured for fixing a hard disk drive. The computer includes a case with a rear wall, and a main board mounted in the case. The main board includes an expansion socket set thereon. The bracket includes a first supporting member including an inserting portion extending therefrom configured for engaging with the expansion socket of the main board, a second supporting member mounted to the first supporting member and configured for being mounted to the rear wall of the computer, and a fixing member mounted to the first supporting member and configured for mounting the hard disk drive.

Other advantages and novel features of the present invention will become more apparent from the following detailed description of an embodiment when taken in conjunction with the accompanying drawings, in which:

### BRIEF DESCRIPTION OF THE DRAWING

FIG. 1 is an exploded, isometric view of a bracket with a hard disk drive in accordance with an embodiment of the present invention; and

FIG. 2 is an assembled, isometric view of FIG. 1.

### DETAILED DESCRIPTION

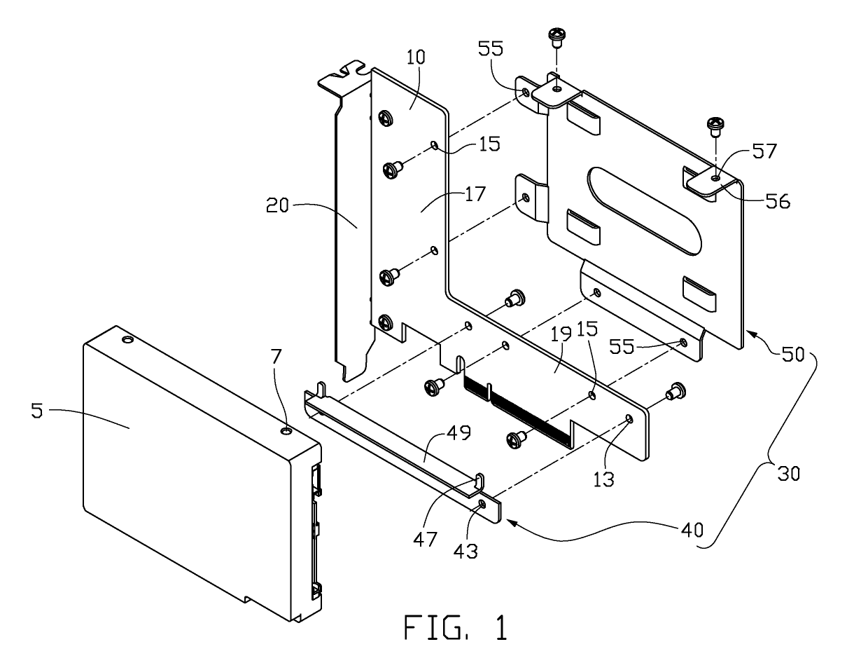

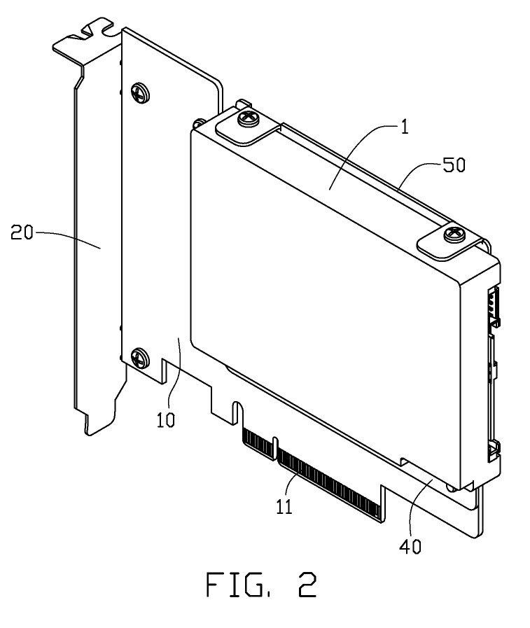

Referring to FIGS. 1 and 2, a bracket for a hard disk drive in accordance with an embodiment of the present invention is provided. The bracket is used for fixing a hard disk drive 5 defining a plurality of assembly holes 7 in a top side and a bottom side thereof to a computer, and includes a first supporting member 10, a second supporting member 20, and a fixing member 30. The hard disk drive 5 is mounted to the bracket by the fixing member 30, and fixed to the computer via the first supporting member 10 and the second supporting member 20. The first supporting member 10 is used for being mounted to a main board of the computer, and the second supporting member 20 is used for mounting to a rear wall of a case of the computer.

The first supporting member 10 is an L-shaped board having a horizontal part 19 and a vertical part 17, and includes an inserting portion 11 extending from a bottom side of the horizontal part 19. The inserting portion 11 is used for being inserting into an expansion socket such as a PCI socket, an AGP socket, or an ISA socket of the main board of the computer to make the first supporting member 10 to be mounted to the main board. In the embodiment, the inserting portion 11 of the first supporting member 10 has a shape receivable by the PCI socket. A plurality of assembly holes 13, 15 for mounting the fixing member 30 is defined in the first supporting member 10 adjacent a top side of the horizontal part 19 and an inner side connecting to the top side of the horizontal part 19, of the vertical part 17. The first supporting member 10 may be a printed circuit board (PCB), a metal board, a plastic board, or any other board capable of being used for supporting things.

The second supporting member 20 is a standard I/O bracket, and is perpendicularly mounted to an outer lateral side of the vertical part 17 of the first supporting member 10.

The fixing member 30 includes a fixing element 40 and a fixing board 50.

The fixing board 50 is mounted to the inner side of the horizontal part 19 and the top side of the vertical part 17 of the first supporting member 10. A plurality of assembly holes 55 is defined in projecting pieces extending from a bottom side and a left side of the fixing board 50 corresponding to the assembly holes 15 of the first supporting member 10, and the fixing board 50 is mounted to the first supporting member 10 via a plurality of screws being inserted through the assembly holes 15 of the first supporting member 10 and engaged in the corresponding assembly holes 55 of the fixing board 50. A plurality of tabs 56 perpendicularly extends from a top side of the fixing board 50, each tab 56 defining an assembly hole 57 therein corresponding to an assembly hole 7 in the top side of the hard disk drive 5. The hard disk drive 5 is mounted to the fixing board 50 via a plurality of screws being inserted through the assembly holes 57 of the fixing board 50 and engaged in the corresponding assembly holes 7 of the hard disk drive 5.

The fixing element 40 is mounted to the first supporting member 10 above the inserting portion 11. A plurality of assembly holes 43 is defined in the fixing element 40 corresponding to the assembly hole 13 of the first supporting member 10, and the fixing element 40 is mounted to the first supporting member 10 via a plurality of screws being inserted through the assembly holes 13 of the first supporting member 10 and engaged in the corresponding assembly holes 43 of the fixing element 40. The fixing element 40 includes a supporting plate 49 perpendicularly extending from a top thereof away from the first supporting member 10. The supporting plate 49 includes a plurality of protrusions 47 extending up therefrom engaging in the corresponding assembly holes 7 in the bottom side of the hard disk drive 5, and the hard disk drive 5 is supported on the supporting plate 49.

Moreover, the first supporting member 10, the second supporting member 20, and the fixing member 30 may be integrally formed.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A bracket mounted to a computer and configured for fixing a hard disk drive, the computer comprising a case with a rear wall, and a main board mounted in the case, the main board comprising an expansion socket set thereon, the bracket comprising:
a first supporting member comprising an inserting portion extending therefrom, the inserting portion configured for engaging with the expansion socket of the main board;
a second supporting member mounted to the first supporting member and configured for being mounted to the rear wall of the computer; and
a fixing member mounted to the first supporting member and configured for mounting the hard disk drive.

2. The bracket as claimed in claim 1, wherein the inserting portion of the first supporting member cooperates with a peripheral component interconnect socket.

3. The bracket as claimed in claim 1, wherein the first supporting member is L-shaped and has a horizontal part and a vertical part.

4. The bracket as claimed in claim 3, wherein the inserting portion extends from a bottom side of the horizontal part of the first supporting member.

5. The bracket as claimed in claim 3, wherein the second supporting member is perpendicularly mounted to an outer lateral side of the first supporting member.

6. The mounting apparatus as claimed in claim 5, wherein the fixing member comprises a fixing board mounted to an inner side of the horizontal part and a top side of the vertical part of the first supporting member and configured for securing the hard disk drive.

7. The bracket as claimed in claim 6, wherein a plurality of tabs perpendicularly extends from a top of the fixing board, the tabs defining a plurality of assembly holes, the assembly holes of the tabs configured for screws extending therethrough to engage with a side of the hard disk drive.

8. The bracket as claimed in claim 7, wherein the fixing member further comprises a fixing element mounted to the first supporting member above the inserting portion and configured for securing an opposite side of the hard disk drive.

9. The bracket as claimed in claim 8, wherein the fixing element of the fixing member comprises a supporting plate perpendicular extending therefrom and configured for supporting the corresponding side of the hard disk drive.

10. The bracket as claimed in claim 9, wherein the supporting plate comprises a plurality of protrusions extending up therefrom to engage with the corresponding side of the hard disk drive.

11. The bracket as claimed in claim 1, wherein the second supporting member is an I/O bracket.

12. The bracket as claimed in claim 1, wherein the first supporting member, the second supporting member, and the fixing member are integrally formed.

13. A bracket for mounting a hard disk drive to a computer that has a printed circuit board with an expansion socket mounted thereto, the bracket comprising:
a member configured for mounting the hard disk drive, the member comprising an inserting portion extending down therefrom configured for inserting into the expansion socket of the printed circuit board.

14. A bracket for mounting a hard disk drive to a computer that has a rear wall, the bracket comprising:
a first member configured for mounting the hard disk drive; and
a second member mounted to a rear side of the first member, configured for being mounted to the rear wall of the computer.
